(19) United States
(12) Patent Application Publication
(10) Pub. No.: US 2022/0347997 A1
(43) Pub. Date: Nov. 3, 2022

(54) METHOD OF MANUFACTURING AN ELECTRONIC PRODUCT HOUSING

(71) Applicant: ZUMING CAO, Shenzhen (CN)

(72) Inventor: ZUMING CAO, Shenzhen (CN)

(21) Appl. No.: 17/359,783

(22) Filed: Jun. 28, 2021

(30) Foreign Application Priority Data
Apr. 29, 2021 (CN) 202110474499.X

(51) Int. Cl. B32B 38/00; B32B 37/12

(52) U.S. Cl. CPC B32B 38/145; B32B 37/12; B32B 2457/00

(57) ABSTRACT

Provided is a method for manufacturing an electronic product housing, where the processed housing includes a transparent housing and a film. The process specifically includes first making a film with a releasable substrate, then making the transparent housing by injection molding, glass or composite film material hot bending, pouring or other processes, and then bonding the transparent housing with the manufactured release film, and finally CNC engraving the bonded product, where the substrate can be retained or peeled off depending on the product characteristics.

### CROSS-REFERENCE TO RELATED APPLICATIONS

This application claims the benefit and priority of China patent application No. 202110474499.X filed on Apr. 29, 2021, disclosure of which is hereby incorporated by reference in its entirety.

### TECHNICAL FIELD

This disclosure relates to a method of manufacturing an electronic product housing. More particularly, this disclosure mainly relates to a method of manufacturing an electronic product housing.

### BACKGROUND

Nowadays, the housings of electronic products, especially the common back covers of mobile phones, mainly use PET material as the substrate of a film. Then the film having color, pattern and texture is bonded with a transparent case, and the electronic product housing is made by the OCA optical adhesive bonding process. The electronic product housing created by the aforementioned bonding process requires directly bending the film before bonding, but the existing process cannot use the heating method to heat the PET film to the softening point for stretching and bonding, because the OCA optical adhesive is only temperature resistant to the point of 90° C. while the softening temperature of PET material is about 150° C. In addition, in the existing bonding process, the corner positions of the housing are prone to delamination after bonding because the PET substrate is easy to rebound at the corners. If the substrate is directly bonded to the electronic product housing with a complex structure without being softened and stretched, then the film will be wrinkled at the corners or R angular positions. Furthermore, because the physical properties of PET cannot meet the stretching requirements of complex structures, the appearance design for products with complex structures is limited. In addition, using the aforementioned PET material and bonding process means a high investment in the bonding equipment, a complicated process, a high cost of optical grade PET material, and an unsatisfactory transmittance of the produce due to the transmittance of the PET material. The aforementioned existing film raw materials (PET material and optical OCA adhesive) used in the housings of electronic products are of optical grade, which all rely on imports, and the procurement cost of the film raw materials is very high. And influenced by the market environment, the existing film raw materials often appear in short supply and high prices, thus bringing inconvenience to the production and operation of the enterprises and increasing the raw material procurement costs of the enterprises. Therefore, there is a need to further research and improve the manufacturing process of the aforementioned housings of electronic products.

### SUMMARY

One of the objectives of the present disclosure is to overcome the above-mentioned shortcomings by providing a method for manufacturing an electronic product housing thus solving the technical problems in the related art that similar processes cannot meet the requirements of high-stretch and complex structure bonding, the corner bonding positions of the shell are prone to delamination, wrinkling, rebound, blistering, and so on, as well as cost problems such as high investment in bonding equipment, complex procedures, and low product yield.

In order to solve the above-mentioned problems, the present disclosure adopts the following technical solutions.

This disclosure provides a method for manufacturing an electronic product housing, the method includes the following operations:

Step A, coating an ink or paint on the surface of a substrate layer, and then curing by heat-baking or by UV irradiation to form a mask layer on the surface of the substrate layer; and then forming a texture layer by performing adhesive transfer or embossing on the mask layer;

Step B, forming an electroplated layer on the surface of the texture layer by PVD electron beam evaporation or magnetron sputtering;

Step C, depending on different types of shells, using any one of pressure-sensitive adhesive, heat-sensitive adhesive, OCA optical adhesive, and UV adhesive to form an adhesive layer on the electroplated layer, thereby obtaining a film;

Step D: bonding the film to the inner surface of the transparent housing through the adhesive layer, or directly performing injection on the surface of the adhesive layer of the film thus making an electronic product housing, and selectively retaining or peeling off the substrate depending on product requirements.

Typically, as a further technical solution, in the step A, before forming the mask layer on the surface of the substrate layer, a release layer is first formed on the surface of the substrate layer, and in the step D, after the film is bonded with the inner surface of the transparent housing, the substrate material layer is peeled off from the mask layer by means of the release layer.

As a further technical solution, the substrate layer in the step A can be selected as a color substrate, and there is no need to form the mask layer on the substrate layer in the case where the color substrate is used.

As a further technical solution, in the step B, any one of the following coloring methods including screen printing, lithographic printing, gravure printing, letterpress printing, digital printing, inkjet printing, spraying, dip dyeing, and coating, or any combination of more than one of the above coloring methods for overlayed coloring may be used to achieve a semi-transparent color layer on the electroplated layer. Then in step C, the adhesive layer may be created on the semi-transparent color layer by any one of OCA adhesive bonding, coating, UV adhesive curing, screen printing, and spraying.

As a further technical solution, the transparent housing in step D is made by injection molding, and a layer of anti-fingerprint wear-resistant hardness coating may be coated on the surface of the injection molded housing, which is then heated and baked, and then UV cured to form a film.

As a further technical solution, the transparent shell in the step D is made of transparent glass after being machined by CNC, softened by high temperature and formed by a mold, and then formed by tempering.

As a further technical solution, the transparent shell is made of thickened transparent glass, the center part of which is hollowed out through CNC machining, and which is then polished and tempered.

As a further technical solution, the transparent shell is a composite plastic film that is softened by high temperature and formed by a mold, and then is coated with a layer of anti-fingerprint wear-resistant hardness coating on the surface (non-bonded surface) by shower coating, spraying or electroplating, and that is finally CNC machined.

As a further technical solution, the mask layer in the step A is manufactured on the surface of the substrate layer using any one of the following methods including screen printing, spraying, lithographic printing, gravure printing, letterpress printing, digital printing, inkjet printing, dip dyeing, coating, and transfer of masking materials, or using any combination of more than one of the above methods in an overlaid manner.

As a further technical solution, in the step A the texture layer is formed on the mask layer by any of the methods of UV transfer of a texture mold, and embossing of a textured roller.

As a further technical solution, in the step C the adhesive layer is made by any one of OCA adhesive bonding, coating, UV adhesive curing, screen printing, and spraying.

As a further technical solution, the bonding procedure between the transparent housing and the film in step D includes the following operations. The transparent housing is placed on the lower mold portion of the bonding mold, where the side to be bonded is facing upwards, the film is placed above the transparent housing, and a gap is left between the film and the housing. Then the air above and below the film in the bonding mold is pumped to a vacuum state of less than 1 pa, and at the same time the bonded film is softened using heating method. Air or high-pressure gas is injected into the other side of the film to be bonded, so that film can be perfectly bonded to the inner surface of the transparent housing by taking advantage of the pressure difference between the upper and lower sides of the film.

Compared with the prior art, the present disclosure provides the following beneficial effects.

1. With the housing made by this process, the substrate can be peeled off. That is, the substrate is only used as a carrier, and so it has no requirements on the optical properties of the substrate. Thus, the raw material of the film is no longer restricted by the expensive imported optical-grade substrates from abroad. The film raw materials can use cheap domestic non-optical substrates, thus meeting the supply of materials, ensuring the delivery of materials, and greatly reducing the price of raw materials.

2. Due to the use of low-temperature thermal deformable and high-stretchable substrates, the problem that the original PET material cannot be bonded to high-stretching and complex structures due to its physical properties is solved. In addition, the bonding of the substrate after thermal deformation, stretching and expanding can solve the problems of bonding wrinkles, delamination, rebound, and blisterings, thus realizing electronic products with more diversified designs, richer structures, and more diversified shapes.

3. Through the peelable substrate process, the product is thinner after the substrate is peeled off.

4. The transmittance of the original PET material is about 91%-93%. Because the middle layer of the film produced by this process has no substrate, the transmittance of the product can be directly increased by 7%-9% on the original basis, which makes the outer housing product more transparent and the color and texture more saturated and dazzling.

5. In cases where a non-peelable substrate is used, the various decorative layers of the product are sandwiched between the substrate and the transparent housing, which can further improve the environmental protection and weather resistance test of the product. In cases where the non-peelable substrate material is used as a color substrate material namely one has colors on its own, then the mask layer may not need to be made.

### BRIEF DESCRIPTION OF DRAWINGS

FIG. 1 is a flowchart of a method for manufacturing an electronic product housing according to an embodiment of the present disclosure.

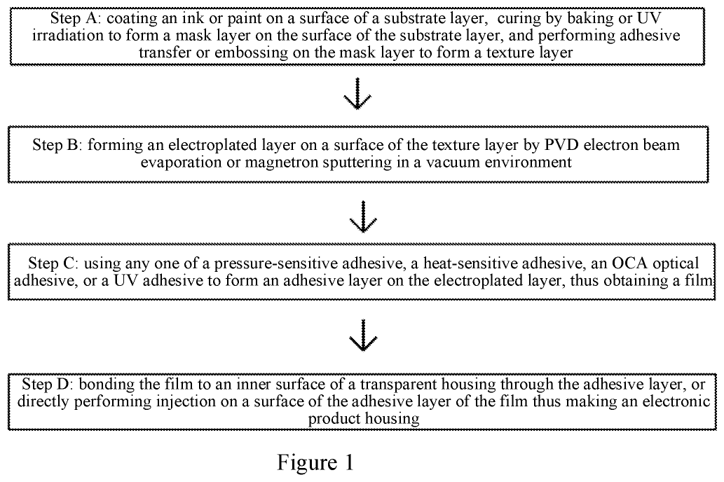

### DETAILED DESCRIPTION OF ILLUSTRATIVE EMBODIMENTS

The present disclosure will be described in further detail below in conjunction with specific embodiments.

An embodiment according to the present disclosure is a method for manufacturing an electronic product housing. The specific steps of the method for manufacturing an electronic product housing are as follows.

In step 1, apply a release layer on one side of the substrate or make a mask layer that can adjust the adhesion to the substrate. If the release layer is made on the substrate layer, then the mask layer may be formed on the release layer by any one of screen printing, spraying, lithographic printing, gravure printing, letterpress printing, digital printing, inkjet printing, dip dyeing, coating, and masking material transfer, or by any combination of the above method in an overlaid manner. If the release layer is not made, the mask layer can be made directly on the substrate layer by the aforementioned methods. If the non-peelable substrate is used as a color substrate, then there is no need to make the mask layer.

In step 2, then a texture layer is made on the mask layer by UV transfer or embossing process, otherwise if the texture layer is not needed, turn directly to step 3.

In step 3, perform vacuum coating on the texture layer by PVD electron beam evaporation or magnetron sputtering to form an electroplated layer. Here, typically, in order to improve the appearance of the bright colors of the electronic product housing, for example, if the electroplated layer is not need, then the step 4 may be directly performed.

In step 4, use screen printing, lithographic printing, gravure printing, letterpress printing, digital printing, inkjet printing, spraying, dip dyeing, or coating method to produce the semi-transparent color layer on the electroplated layer. Otherwise if the semi-transparent color layer is not needed, turn directly to step 5.

In step 5, apply a layer of adhesive on the semi-transparent color layer by bonding, coating, UV adhesive curing, screen printing, and spraying on the semi-permeable color layer to form an adhesive layer, thereby obtaining a film. The aforementioned adhesive layer can be selected as any one of pressure-sensitive adhesive, heat-sensitive adhesive, OCA optical adhesive, and UV adhesive depending on different types of housings.

In step 6, bonding the film to the inner surface of the transparent housing through the adhesive layer, or directly performing injection on the surface of the adhesive layer of the film thus making an electronic product housing, and selectively retaining or peeling off the substrate depending on product requirements.

The operation method of directly injecting on the surface of the film adhesive layer in the above step 6 is as follows. Place the film obtained in step 5 in the mold cavity, then close the mold, and then inject the plastic grains into the mold cavity in the form of liquid by being heated using screw heating on the film bonding layer to form an electronic product housing, where the screw temperature is 230-360° C., the sequence of actions is: place the film→close the mold→injecting molding on the bonding layer→cool down→open the mold→remove the workpiece.

The transparent housing in the above step 6 can be obtained in the following three ways.

1. The transparent housing can be made by injection molding with grains, and the surface of the injection molded shell is coated with an anti-fingerprint and wear-resistant hardness coating, which is subjected to heating and baking, and cured by UV ultraviolet radiation thus forming a film.

2. The transparent shell can also be made of transparent glass. There are two ways. One is a 3D transparent glass housing, where the transparent glass is machined by CNC, softened by high temperature and formed by a mold, and then tempered. The other is to use thickened transparent glass, hollow out the excess part in the middle by CNC machining, and then polish and temper it.

3. The transparent shell can also be a composite plastic film that is softened by high temperature and formed by a mold, and then is coated with a layer of anti-fingerprint wear-resistant hardness coating on the surface by shower coating, spraying or electroplating, and that is finally CNC machined.

As mentioned in step 1, the substrate in the above method is a film or roll, and the substrate layer can be of two types: peelable and non-peelable, including but not limited to PC, PET, PMMA+PC, PP, PVC, PS, ABS, PMMA, TPU, TPE and other materials.

In this embodiment, a peelable substrate material layer is used, and a release layer needs to be added between the mask layer and the substrate material layer, or alternatively a mask layer that can adjust the adhesion to the substrate material is required. The release layer is made of polyurethane or polyester materials. After the film is attached to the inner surface of the transparent housing, the substrate material layer is peeled off from the release layer or the mask layer. In this embodiment, based on the above process steps, it can be seen that the mask layer is formed by coating ink or paint on the surface of the substrate layer, and then curing it by baking or UV irradiation. The texture layer is formed on the mask layer by means of adhesive transfer or embossing. The electroplated layer is formed on the surface of the texture layer by means of PVD electron beam evaporation or magnetron sputtering. The semi-transparent color layer is a semi-transparent pattern layer, which creates a color layer on the electroplated layer by any one or any combination of the following coloring methods, including screen printing, lithographic printing, gravure printing, letterpress printing, digital printing, inkjet printing, spraying, dip dyeing, coating, and so on. The adhesive layer is formed on the semi-transparent color layer by any one selected from the following methods, including OCA adhesive bonding, coating, UV adhesive curing, screen printing, and spraying.

In this embodiment, the transparent housing is placed on the lower mold portion of the bonding mold, where the side to be bonded is facing upwards, the film is placed above the transparent housing, and a gap is left between the film and the housing. Then the air above and below the film in the bonding mold is pumped to a vacuum state of less than 1 pa, and at the same time the bonded film is softened using heating method. Air or high-pressure gas is injected into the other side of the film to be bonded, so that film can be perfectly bonded to the inner surface of the transparent housing by taking advantage of the pressure difference between the upper and lower sides of the film.

Based on the above-mentioned embodiments according to the present disclosure, various techniques for processing the electronic product housing based on the above-mentioned structures are described in detail as follows.

First, the following ten processing methods are possible for creating the above-mentioned mask layer on the film.

The first is screen printing. Use a screen printer to pour the masking ink into the screen, use a scraper to leak the ink through the screen to the surface of the substrate or release layer, and cure the ink by heating and baking or UV curing, thus forming a mask layer. The baking time is 30-90 minutes, the baking temperature is 60° C.-110° C., and the number of printing times is 2-6. The energy of UV curing is 800-5000 mJ/cm², and the curing time is 2-5 seconds.

The second is spraying. Use a spray gun to directly spray the paint on the surface of the substrate or release layer, and cure the ink to form a mask layer by heating and baking or curing with a UV ultraviolet lamp. The baking time is 30-90 minutes, the baking temperature is 60° C.-110° C., and the number of sprayings is 1-3 times. The energy of UV curing is 800-5000 mJ/cm², and the curing time is 2-5 seconds.

The third type is lithographic printing. Use a CTP printing plate making machine to expose the PS board according to the customer's covering requirements to get the dots to be printed, and then load the exposed PS board on the lithographic printing machine table, transfer the ink to the PS board, which then transfers the ink to the rubber cloth, and the rubber cloth transfers the ink to the substrate layer or the release layer, and then cures by UV ultraviolet lamp exposure to achieve the mask layer. The number of printing is 3-7 times, and the curing condition each time is 800-5000 mJ/cm².

The fourth type is gravure printing. A gravure plate is made through engraving, etching, and electronic engraving according to customer requirements. Load the gravure plate into the gravure printing machine, apply ink on the entire surface of the gravure plate, and then use a squeegee to remove the ink in the blank part, so that the ink only retains in the groove part, and then under a great pressure, the ink is transferred to the substrate layer or the release layer, and then the ink is cured by UV exposure to form a mask layer. The energy is 1000-3000 mJ/cm², and the curing time is 1-3 seconds.

The fifth type is letterpress printing. Use photopolymer to make relief plates on wood boards and lithographic plates according to the customer's covering requirements. The ink is evenly distributed through the ink supply device of the letterpress printing machine, and then the ink is transferred to the printing plate through the ink roller, and then the masking ink is transferred to the substrate or the release layer through the printing plate, and then heated and baked or exposed to UV ultraviolet lamp radiation thus achieving the mask layer. The baking time is 3-5 minutes, and the baking temperature is 60° C.-110° C. The UV curing energy is 1000-3000 mJ/cm², and the curing time is 1-3 seconds.

The sixth type is digital printing. Output the graphics and text information to the computer, perform innovative design, modification, and layout to achieve the color pattern that the customer needs. After RIP processing, it becomes the corresponding monochrome pixel digital signals which are sent to the laser controller, which emits the corresponding laser beam to scan the printing cylinder. The printing cylinder (without printing plate) made of photosensitive material is exposed to form graphics and text that can absorb ink or toner, and then transferred to the surface of the electroplating layer to form a semi-transparent color layer.

The seventh type is inkjet printing. Use piezoelectric inkjet or thermal inkjet to spray paint directly on the surface of the electroplated layer to form a semi-transparent color layer according to the customer's color requirements.

The eighth method is dip dyeing. Put the substrate into the dip tank, and through the dye bath cycle or the movement of the dyed object, the dye is gradually dyed onto the substrate layer or the release layer, and the substrate is then taken out and heated and baked, and further cured to form a mask layer. The baking time is 30-90 minutes, the baking temperature is 60° C.-110° C., and the number of dip dyeing is 1-3 times.

The ninth type is coating. Depending on the characteristics of different coatings, the coating equipment can be used to uniformly coat the masking coating on the substrate layer or the release layer by means of wire rods, anilox rollers, comma blades, slit heads, etc., and by heating baking or UV ultraviolet lamp curing method, the coating is cured to form a mask layer. The baking time is 3-5 minutes, and the baking temperature is 60° C.-110° C. The energy of UV curing is 800-5000 mJ/cm², and the curing time is 1-3 seconds.

The tenth type is the transfer of the mask layer. Use a transfer adhesive to transfer the mask layer on the masking material to the substrate layer or the release layer by UV transfer equipment and form the mask layer use UV ultraviolet lamp exposure and curing. The curing energy is 800-5000 mJ/cm², and the curing time is 2-5 seconds.

The texture layer on the mask layer in the above film can also be processed in three alternative ways.

The first is the film substrate UV transfer texture production method. Pour a UV adhesive onto a textured mold, place the substrate (covering side facing downward), use a roller press to coat the UV texture on the entire surface evenly with a layer of UV adhesive, and then use a UV lamp for exposure. After exposure for 3-5 seconds for curing, the substrate is peeled off and the UV adhesive texture is transferred to the mask layer. The texture layer material is acrylate (UV adhesive), and the curing energy is 1000-3500 mJ/cm².

The second method is roll material substrate UV transfer texture production method. Use a coater to uniformly apply UV adhesive to the mask layer, then use a textured roller to completely seal the coating adhesive, and directly use a UV lamp for exposure. After exposure for 1-3 seconds and curing, the substrate is separated from the textured roller, and finally the UV texture is obtained on the mask layer of the roll material and then the material is film-coated and reeled. The texture layer material is acrylate (UV adhesive), and the curing energy is 1000-3500 mJ/cm².

The third method is roll material embossing method. Use a coater to evenly apply polyurethane adhesive to the mask layer, bake at 60-120° C. for 2-5 minutes so that the adhesive is hardened to form a film, and then use a roller with high temperature texture at 160° C. to directly press the hardened adhesive out of the texture and then separate the substrate from the textured roller, and finally, after the UV texture is obtained on the mask layer of the roll material, the material is film-coated and reeled.

The electroplated layer in the above film can also be processed using the following two alternative methods.

The first type is PVD electron beam evaporation. Put the substrate into the coating equipment, pump the air in the coating equipment to a vacuum of 8.0×10-2-2.0×10-4 pa and directly heat the evaporation film material using electron beams so that the evaporation film material is evaporated and deposited on the texture surface of the substrate, thus depositing an electroplated layer on the texture surface. According to this method, multiple electroplated layers may be used in combination according to product color and product performance requirements.

The second type is magnetron sputtering. Put the substrate into the coating equipment, pump the air in the coating equipment to a vacuum of 8.0×10-2-2.0×10-4 pa and bombard the surface of the substrate using an ion source, and then an electric field is used to cause gas discharge to generate gas ionization. The positive ions bombard the cathode target at a high speed under the action of a magnetic field, causing atoms or molecules of the cathode target to sputter and fly to the substrate located at the anode thus depositing it on the textured surface to form an electroplating layer. According to this method, multiple electroplated layers may be used in combination according to product color and product performance requirements.

The semi-transparent color layer in the above-mentioned film has a semi-transparent pattern, which can be processed in the following nine alternative ways.

The first is screen printing. Use a screen printer to pour the semi-transparent ink into the screen, use a scraper to leak the ink through the screen to the surface of the electroplating layer, and cure the ink by heating and baking or UV lamp exposure and curing, thus forming a semi-transparent layer. The baking time is 30-90 minutes, the baking temperature is 60° C.-110° C., and the number of printing times is 1-3. The UV curing energy is 800-5000 mJ/cm², and the curing time is 2-5 seconds.

The second type is lithographic printing. Use the CTP printing plate making machine to expose the dots of the PS board according to the customer's color requirements to get the dots that need to be printed, and at the same time adjust the ink according to the color requirements. Then load the exposed PS board on the lithographic printing machine table, transfer the ink to the PS board, which then transfers the ink to the rubber cloth, and the rubber cloth transfers the ink to the electroplated layer, and then cure the ink by UV ultraviolet lamp exposure to achieve the semi-transparent layer. The number of printing is 2-7 times, and the curing condition each time is 800-5000 mJ/cm².

The third type is gravure printing. A gravure plate is made through engraving, etching, and electronic engraving according to color requirements. Load the gravure plate into the gravure printing machine, apply ink on the entire surface of the gravure plate, and then use a squeegee to remove the ink in the blank part, so that the ink only retains in the groove part, and then under a great pressure, the ink is transferred to the electroplated layer, and then the ink is cured by UV exposure to form a semi-transparent layer. The number of printing times is 2-7 times, the energy is 1000-3000 mJ/cm², and the curing time is 1-3 seconds.

The fourth type is letterpress printing. Use photopolymer to make relief plates on wood boards and lithographic plates according to the color requirements. The ink is evenly distributed through the ink supply device of the letterpress printing machine, and then the ink is transferred to the printing plate through the ink roller, and then the color ink is transferred to the electroplated layer through the printing plate, and then heated and baked or exposed to UV ultraviolet lamp radiation thus achieving the semi-transparent layer. The baking time is 3-5 minutes, and the baking temperature is 60° C.-110° C. The UV curing energy is 1000-3000 mJ/cm², and the curing time is 1-3 seconds.

The fifth type is digital printing. Output the graphics and text information to the computer, perform innovative design, modification, and layout to achieve the color pattern that the customer needs. After RIP processing, it becomes the corresponding monochrome pixel digital signals which are sent to the laser controller, which emits the corresponding laser beam to scan the printing cylinder. The printing cylinder (without printing plate) made of photosensitive material is exposed to form graphics and text that can absorb ink or toner, and then transferred to the surface of the electroplating layer to form a semi-transparent color layer.

The sixth type is inkjet printing. Use piezoelectric inkjet or thermal inkjet to spray paint directly on the surface of the electroplated layer to form a semi-transparent color layer according to the customer's color requirements. The seventh type is spraying. Use a spray gun to directly spray the paint on the surface of the electroplated layer according to the customer's color requirements, and cure the ink to form a semi-transparent layer by heating and baking or curing with a UV ultraviolet lamp exposure and curing. The baking time is 30-90 minutes, the baking temperature is 60° C.-110° C., and the number of sprayings is 2-5 times. The energy of UV curing is 800-5000 mJ/cm², and the curing time is 2-5 seconds.

The eighth method is dip dyeing. Put the substrate into the dip tank, and through the dye bath cycle or the movement of the dyed object, the dye is gradually dyed onto the electroplated layer, and the substrate is then taken out and heated and baked, and further cured to form a semi-transparent layer. The number of dip dyeing is 1-3 times, and the dyeing time is 5-15 minutes/each time. The baking time is 30-90 minutes, and the baking temperature is 60° C.-110° C.

The ninth type is coating. Depending on the characteristics of different coatings, the coating equipment can be used to uniformly coat the color coating on the electroplated by means of wire rods, anilox rollers, comma blades, slit heads, etc., and by heating baking or UV ultraviolet lamp curing method, the coating is cured to form a semi-transparent layer. The baking time is 3-5 minutes, and the baking temperature is 60° C.-110° C. The energy of UV curing is 800-5000 mJ/cm², and the curing time is 1-3 seconds.

The adhesive layer in the above-mentioned film can be produced in the following four alternative ways.

The first is the OCA adhesive bonding method. Buy OCA adhesive directly and use a lithographic laminator to bond the OCA adhesive to the semi-transparent color layer to form an adhesive layer.

The second is to use a coating machine to uniformly coat the adhesive on the semi-transparent color layer using wire rods, anilox rollers, comma doctor blades, slit heads or other coating methods, depending on the characteristics of pressure-sensitive adhesives, heat-sensitive adhesives, hot melt adhesives and other adhesive adhesives. Further cure the ink to form an adhesive layer by heating and curing. The baking time is 2-5 minutes, and the baking temperature is 60° C.-110° C.

The third is to use UV adhesive. Specifically, the UV adhesive is applied to the semi-transparent color layer by wire rod, screen printing or spraying, and after the adhesive is self-leveling, it is directly bonded to the transparent housing by a vacuum laminator, and then exposed and cured by UV ultraviolet lamp. The curing energy is 1000-3000 mJ/cm², and the curing time is 2-5 seconds.

The fourth is to use a screen printing machine to pour pressure-sensitive adhesive, heat-sensitive adhesive, and hot melt adhesive into the screen, use a squeegee to leak the adhesive through the screen to the surface of the semi-transparent color layer, and cure the adhesive to form an adhesive layer by heating and baking curing. The baking time is 2-5 minutes, and the baking temperature is 60° C.-110° C.

The above-mentioned transparent housing can adopt the following 3 processing methods.

1. Direct 3D structured transparent glass housing or 3.5D structured transparent glass can be used to make the housing. The 3D transparent glass housing can be made of transparent glass, processed by CNC, and then softened at high temperature, formed by mold, and then processed with glass tempering. The 3.5D structured transparent glass can be thickened glass, and then the middle part is hollowed out through CNC processing and then polished, and after that the glass is tempered.

2. Injection molding the transparent housing. The plastic injection grains are injected into the mold cavity by being heated in the form of screw heating into a liquid state. The screw temperature is 230-360 degrees Celsius. The sequence of actions is: mold closing→injection→cooling→mold opening→removal of workpiece. Then use an anti-fingerprint and wear-resistant hardness coating on the surface of the injection molded housing material to spray or curtain coating the surface (non-bonding surface) of the injection molded housing material, and then cure the coating thus forming a film use heating and baking or UV ultraviolet lamp radiation, thereby forming surface properties. The baking time is 3-5 minutes, and the baking temperature is 50° C.-100° C. The energy of UV curing is 2000-4000 mJ/cm², and the curing time is 2-5 seconds.

3. Die-casting the transparent housing. Depending on the physical properties of different materials, the material is melted at high temperatures and poured into the profiling mold and cooled. After being taken out, the feed port is CNC processed.

The bonding method between the transparent housing and the film is as follows.

The transparent housing is placed on the lower mold portion of the bonding mold, where the side to be bonded is facing upwards, the film is placed above the transparent housing, and a gap is left between the film and the housing. Then the air above and below the film in the bonding mold is pumped to a vacuum state of less than 1 pa, and at the same time the bonded film is softened using heating method. Air or high-pressure gas is injected into the other side of the film to be bonded, so that film can be perfectly bonded to the inner surface of the transparent housing by taking advantage of the pressure difference between the upper and lower sides of the film. According to the characteristics of the adhesive, the product can be heated or pressurized to increase the viscosity of the adhesive after the product is bonded.

In addition, in the description of the above embodiments of the present disclosure, it should be particularly noted that because customers have different requirements for appearance effects, different processing conditions may exist due to different characteristics of raw materials, adhesives, and inks used.

In addition to the above, it should be noted that by phrases such as “in one embodiment”, “in another embodiment”, “in some embodiments”, etc. mentioned in this specification, they mean that the specific features, structures, or characteristics described in connection with the embodiment are included in at least one embodiment described generally in this application. The occurrence of the same expression in multiple places in the specification does not necessarily refer to the same embodiment. Furthermore, when describing a specific feature, structure or characteristic in connection with any embodiment, it is claimed that implementing such features, structures or characteristics in connection with other embodiments shall also fall in the scope of protection of the present disclosure.

Although the present disclosure has been described with reference to a number of explanatory embodiments of the present disclosure, it should be understood that many other modifications and embodiments can be devised by those having ordinary skill in the art, and these modifications and embodiments will fall in the scope and spirit of the principles disclosed in this application. More specifically, within the scope of the disclosure of this specification and the claims, various modifications and improvements can be made to the components or parts and/or the arrangements or configurations of the subject combined arrangement. In addition to the modification and improvement of the component or parts or the arrangement or configuration, other uses will also be evident to those having ordinary skill in the art.

What is claimed is:

1. A method of manufacturing an electronic product housing, comprising:
operation A: coating an ink or paint on a surface of a substrate layer, curing by baking or UV irradiation to form a mask layer on the surface of the substrate layer, and performing adhesive transfer or embossing on the mask layer to form a texture layer;
operation B: forming an electroplated layer on a surface of the texture layer by PVD electron beam evaporation or magnetron sputtering in a vacuum environment;
operation C: using any one of a pressure-sensitive adhesive, a heat-sensitive adhesive, an OCA optical adhesive, or a UV adhesive to form an adhesive layer on the electroplated layer, thus obtaining a film; and
operation D: bonding the film to an inner surface of a transparent housing through the adhesive layer, or directly performing injection on a surface of the adhesive layer thus making the electronic product housing.

2. The method of claim 1, wherein in operation A, before forming the mask layer on the surface of the substrate layer, a release layer is first formed on the surface of the substrate layer, and wherein in operation D, after the film is bonded with the inner surface of the transparent housing, the substrate material layer is peeled off from the mask layer by means of the release layer.

3. The method of claim 1, wherein the substrate layer in operation A is a color substrate which comprises colors on its own, and the mask layer needs not be formed on the substrate layer.

4. The method of claim 1, wherein in operation B, a semi-transparent color layer is formed on the electroplated layer by any one or any combination of the following coloring methods: screen printing, lithographic printing, gravure printing, letterpress printing, digital printing, inkjet printing, spraying, dip dyeing, and coating; and
where in operation C, the adhesive layer is formed on the semi-transparent color layer by any one of OCA adhesive bonding, coating, UV adhesive curing, screen printing, and spraying.

5. The method of claim 2, wherein in operation B, a semi-transparent color layer is formed on the electroplated layer by any one or any combination of the following coloring methods: screen printing, lithographic printing, gravure printing, letterpress printing, digital printing, inkjet printing, spraying, dip dyeing, and coating; and
where in operation C, the adhesive layer is formed on the semi-transparent color layer by any one of OCA adhesive bonding, coating, UV adhesive curing, screen printing, and spraying.

6. The method of claim 1, wherein in operation D the transparent housing is made by injection molding, and a layer of anti-fingerprint wear-resistant hardness coating is coated on an outer surface of the injection molded housing, which is then heated and baked, and then UV cured.

7. The method of claim 1, wherein in operation D the transparent housing is made of a transparent glass after being machined by CNC, softened by high temperature and formed by a mold, and then formed by tempering.

8. The method of claim 1, wherein the transparent housing is a composite plastic film that is softened by high temperature and formed by a mold, and then is coated with a layer of anti-fingerprint wear-resistant hardness coating on the surface by shower coating, spraying or electroplating, and that is finally formed by CNC machining.

9. The method of claim 1, wherein the transparent housing is made of a thickened transparent glass, a center portion of which is hollowed out through CNC machining, and which is then polished and tempered.

10. The method of claim 1, wherein in operation D the transparent housing is bonded with the film through the following process in which the transparent housing is placed on a lower mold portion of a bonding mold where a side to be bonded is facing upwards, the film is placed above the transparent housing, and a gap is left between the film and the housing; then the air above and below the film in the bonding mold is pumped to a vacuum state of less than 1 pa, and at the same time the bonded film is softened using a heating method, then air or a high-pressure gas is injected into another side of the film to be bonded, so that film is perfectly bonded to the inner surface of the transparent housing by taking advantage of a pressure difference between the upper and lower sides of the film.

11. The method of claim 1, wherein in operation A the mask layer is created on the surface of the substrate layer using any one or any combination of the following methods: screen printing, spraying, lithographic printing, gravure printing, letterpress printing, digital printing, inkjet printing, dip dyeing, coating, and transfer of masking materials.

12. The method of claim 1, wherein in operation A the texture layer is formed on the mask layer by any of the following methods: texture mold UV transfer, and embossing with a textured roller.

13. The method of claim 1, wherein in operation C the adhesive layer is selected as any one of a pressure-sensitive adhesive, a heat-sensitive adhesive, an OCA optical adhesive, or a UV adhesive depending on different types of housings.
